(19) United States
(12) Patent Application Publication
(10) Pub. No.: US 2026/0182202 A1
(43) Pub. Date: Jun. 25, 2026

(54) Display Panel and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Yige Qi, Beijing (CN); Zhimeng Shao, Beijing (CN); Gaokun Huang, Beijing (CN); Jinyu Li, Beijing (CN); Tiancheng Yu, Beijing (CN); Pingchuan Zeng, Beijing (CN); Bingchuan Li, Beijing (CN)

(21) Appl. No.: 18/833,503

(22) PCT Filed: Sep. 18, 2023
(86) PCT No.: PCT/CN2023/119510

§ 371 Date: Jul. 26, 2024

(51) Int. Cl. H10K 59/80; H10K 50/12; H10K 101/20; H10K 102/00

(52) U.S. Cl. CPC H10K 59/80518; H10K 50/12; H10K 59/873; H10K 59/879; H10K 2101/20; H10K 2102/351

(57) ABSTRACT

A display panel includes: a first electrode layer, a second electrode layer and a light-emitting layer. The first electrode layer includes a reflective electrode layer. The second electrode layer is arranged opposite to the first electrode layer, and the second electrode layer includes a transflective electrode layer. The light-emitting layer is located between the first electrode layer and the second electrode layer. The light-emitting layer includes a plurality of light-emitting portions. A material of each light-emitting portion includes a host material and a light-emitting material. The light-emitting portions include a plurality of red light-emitting portions, a plurality of blue light-emitting portions and a plurality of green light-emitting portions. A light-emitting material of at least one of the red light-emitting portions includes a deep red phosphorescent material. A peak of a photoluminescence spectrum of the deep red phosphorescent material is in a range of 630 nm to 650 nm.

### CROSS-REFERENCE TO RELATED APPLICATION

This application is the United States national phase of International Patent Application No. PCT/CN2023/119510, filed Sep. 18, 2023, the disclosure of which is hereby incorporated by reference in its entirety.

### BACKGROUND OF THE INVENTION

### Field of the Invention

The present disclosure relates to the field of display technologies, and in particular, to a display panel and a display apparatus.

### Description of Related Art

Active matrix organic light-emitting devices (AMOLEDs) have advantages such as low power consumption, high contrast and bright colors. As people put forward higher demands on the picture quality of games, audio and video notebooks or desktop computers with integrated AMOLED display screens, high color gamut display technology suitable for high dynamic range (HDR) and matching the BT2020 color gamut standard has come into being.

### SUMMARY OF THE INVENTION

In an aspect, a display panel is provided. The display panel includes: a first electrode layer, a second electrode layer and a light-emitting layer. The first electrode layer includes a reflective electrode layer. The second electrode layer is arranged opposite to the first electrode layer, and the second electrode layer includes a transflective electrode layer. The light-emitting layer is located between the first electrode layer and the second electrode layer, and the light-emitting layer includes a plurality of light-emitting portions. A material of each of the plurality of light-emitting portions includes: a host material and a light-emitting material. The plurality of light-emitting portions include a plurality of red light-emitting portions, a plurality of blue light-emitting portions and a plurality of green light-emitting portions. A light-emitting material of at least one red light-emitting portion of the plurality of red light-emitting portions includes a deep red phosphorescent material, and a peak of a photoluminescence spectrum of the deep red phosphorescent material is in a range of 630 nm to 650 nm.

In some embodiments, a chromaticity coordinate Rx of red light emitted by the deep red phosphorescent material is in a range of 0.703 to 0.705.

In some embodiments, the deep red phosphorescent material is selected from any one of: an iridium complex, a platinum complex, a zinc complex, a lithium complex, and a beryllium complex.

In some embodiments, a material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

In some embodiments, a chromaticity coordinate Gx of green light emitted by the deep green fluorescent material is in a range of 0.155 to 0.165.

In some embodiments, the deep green fluorescent material is selected from any one of: coumarins, carbazole derivatives, diaminoanthracene derivatives, and pyrazoloquinoxaline derivatives.

In some embodiments, the display panel further includes a covering layer disposed on a side of the second electrode layer away from the light-emitting layer; a thickness of the second electrode layer is in a range of 160 Å to 170 Å; and a thickness of the covering layer is in a range of 950 Å to 1000 Å.

In some embodiments, the display panel further includes a first encapsulation layer disposed on a side of the covering layer away from the second electrode layer. The first encapsulation layer is of a multi-layer structure, and includes a first encapsulation sub-layer, a second encapsulation sub-layer and a third encapsulation sub-layer that are sequentially arranged in a direction away from the covering layer; a refractive index of the covering layer is greater than a refractive index of the first encapsulation sub-layer; the refractive index of the first encapsulation sub-layer is less than a refractive index of the second encapsulation sub-layer; and the refractive index of the second encapsulation sub-layer is greater than a refractive index of the third encapsulation sub-layer.

In some embodiments, the refractive index of the covering layer is in a range of 1.7 to 1.8; the refractive index of the first encapsulation sub-layer is in a range of 1.4 to 1.52; the refractive index of the second encapsulation sub-layer is in a range of 1.7 to 1.8; and the refractive index of the third encapsulation sub-layer is in a range of 1.55 to 1.65.

In some embodiments, the display panel further includes: an optical control layer and a first encapsulation layer. The optical control layer is disposed on a side of the covering layer away from the second electrode layer. The first encapsulation layer is of a single-layer structure and is disposed on a side of the optical control layer away from the covering layer.

In some embodiments, the display panel further includes a second encapsulation layer and a third encapsulation layer sequentially disposed on a side of the first encapsulation layer away from the covering layer.

In some embodiments, in a case where the display panel includes the first encapsulation layer, the second encapsulation layer, and the third encapsulation layer, a material of the first encapsulation layer includes silicon oxynitride, a material of the second encapsulation layer includes an organic material, and a material of the third encapsulation layer includes silicon nitride.

In another aspect, a display panel is provided. The display panel includes: a first electrode layer, a second electrode layer and a light-emitting layer. The first electrode layer includes a reflective electrode layer. The second electrode layer is arranged opposite to the first electrode layer, and the second electrode layer includes a transflective electrode layer. The light-emitting layer is located between the first electrode layer and the second electrode layer. The light-emitting layer includes a plurality of light-emitting portions, and a material of each of the plurality of light-emitting portions includes: a host material and a light-emitting material. The plurality of light-emitting portions include a plurality of red light-emitting portions, a plurality of blue light-emitting portions and a plurality of green light-emitting portions.

A light-emitting material of a red light-emitting portion further includes a red thermally activated delayed fluorescence material and a deep red fluorescent material, and a peak of a photoluminescence spectrum of the deep red fluorescent material is in a range of 630 nm to 650 nm; in the red light-emitting portion, a ratio of mass of the deep red fluorescent material to a sum of mass of a host material, the red thermally activated delayed fluorescence material and the deep red fluorescent material is in a range of 0.4% to 0.6%.

In some embodiments, a chromaticity coordinate Rx of red light emitted by the deep red fluorescent material is in a range of 0.703 to 0.705.

In some embodiments, the deep red fluorescent material includes any one of: dicyanomethylene-4H-pyran (DCM)-based dopants, DCM derivative dopants, auxiliary dopants, conjugated condensed rings, porphyrin macrocycles, and aromatic acid.

In some embodiments, a material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

In some embodiments, a chromaticity coordinate Gx of green light emitted by the deep green fluorescent material is in a range of 0.155 to 0.165.

In some embodiments, the deep green fluorescent material is selected from any one of: coumarins, carbazole derivatives, diaminoanthracene derivatives, and pyrazoloquinoxaline derivatives.

In yet another aspect, a display panel is provided. The display panel includes: a first electrode layer, a second electrode layer and a light-emitting layer. The first electrode layer includes a reflective electrode layer. The second electrode layer is arranged opposite to the first electrode layer, and the second electrode layer includes a transflective electrode layer. The light-emitting layer is located between the first electrode layer and the second electrode layer. The light-emitting layer includes a plurality of light-emitting portions, and a material of each of the plurality of light-emitting portions includes: a host material and a light-emitting material. The plurality of light-emitting portions include a plurality of red light-emitting portions, a plurality of blue light-emitting portions and a plurality of green light-emitting portions.

A material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

In some embodiments, a chromaticity coordinate Gx of green light emitted by the deep green fluorescent material is in a range of 0.155 to 0.165.

In some embodiments, the deep green fluorescent material is selected from any one of: coumarins, carbazole derivatives, diaminoanthracene derivatives, and pyrazoloquinoxaline derivatives.

In yet another aspect, a display device is provided. The display device includes: the display panel as described in any of the above embodiments; and the display device further includes a driver chip for driving the display panel to display images.

### BRIEF DESCRIPTION OF THE DRAWINGS

The terms Fig., Figs., Figure, and Figures are used interchangeably in the specification to refer to the corresponding figures in the drawings.

In order to describe technical solutions in the present disclosure more clearly, the accompanying drawings to be used in some embodiments of the present disclosure will be introduced briefly. However, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments of the present disclosure;

FIG. 2 is a structural diagram of a display panel, in accordance with some embodiments of the present disclosure;

FIG. 3 is a diagram showing spectra of different light-emitting materials, in accordance with some embodiments of the present disclosure;

FIG. 4 is a diagram showing a test result of a relationship between chromaticity coordinate and luminous efficiency, in accordance with some embodiments of the present disclosure;

FIG. 5 is a diagram showing a test result of a relationship between chromaticity coordinates, in accordance with some embodiments of the present disclosure;

FIG. 6 is a diagram showing a test result of a relationship between a chromaticity coordinate and a color gamut, in accordance with some embodiments of the present disclosure;

FIG. 7 is a diagram showing a test result of a relationship between a chromaticity coordinate and color gamut coverage, in accordance with some embodiments of the present disclosure;

FIG. 8 is a diagram showing a test result of chromaticity coordinates, in accordance with some embodiments of the present disclosure;

FIG. 9 is a diagram showing a test result of color shift of white light at viewing angles, in accordance with some embodiments of the present disclosure;

FIG. 10 is a diagram showing a test result of brightness attenuation curves of white light at viewing angles, in accordance with some embodiments of the present disclosure;

FIG. 11 is a diagram showing a test result of brightness attenuation curves of red light at viewing angles, in accordance with some embodiments of the present disclosure;

FIG. 12 is a diagram showing a test result of brightness attenuation curves of green light at viewing angles, in accordance with some embodiments of the present disclosure;

FIG. 13 is a diagram showing a test result of brightness attenuation curves of blue light at viewing angles, in accordance with some embodiments of the present disclosure;

FIG. 14 is a diagram showing a test result of chromaticity coordinates, in accordance with some other embodiments of the present disclosure;

FIG. 15 is a diagram showing a test result of color shift of white light at viewing angles, in accordance with some other embodiments of the present disclosure;

FIG. 16 is a structural diagram of another display panel, in accordance with some embodiments of the present disclosure;

FIG. 17 is a diagram showing a test result of brightness attenuation curves of red light at viewing angles, in accordance with some other embodiments of the present disclosure;

FIG. 18 is a diagram showing a test result of brightness attenuation curves of green light at viewing angles, in accordance with some other embodiments of the present disclosure;

FIG. 19 is a diagram showing a test result of brightness attenuation curves of blue light at viewing angles, in accordance with some other embodiments of the present disclosure;

FIG. 20 is a diagram showing a test result of chromaticity coordinates, in accordance with yet some other embodiments of the present disclosure;

FIG. 21 is a diagram showing a test result of color shift of white light at viewing angles, in accordance with yet some other embodiments of the present disclosure;

FIG. 22 is a diagram showing a test result of brightness attenuation curves of red light at viewing angles, in accordance with yet some other embodiments of the present disclosure;

FIG. 23 is a diagram showing a test result of brightness attenuation curves of green light at viewing angles, in accordance with yet some other embodiments of the present disclosure;

FIG. 24 is a diagram showing a test result of brightness attenuation curves of blue light at viewing angles, in accordance with yet some other embodiments of the present disclosure;

FIG. 25 is a diagram showing a test result of chromaticity coordinates, in accordance with yet some other embodiments of the present disclosure;

FIG. 26 is a diagram showing a test result of color shift of white light at viewing angles, in accordance with yet some other embodiments of the present disclosure;

FIG. 27 is a diagram showing a test result of a relationship between chromaticity coordinate and luminous efficiency, in accordance with some other embodiments of the present disclosure;

FIG. 28 is a diagram showing a test result of a relationship between chromaticity coordinates, in accordance with some other embodiments of the present disclosure;

FIG. 29 is a diagram showing a test result of a relationship between a chromaticity coordinate and a color gamut, in accordance with some other embodiments of the present disclosure;

FIG. 30 is a diagram showing a test result of a relationship between a chromaticity coordinate and color gamut coverage, in accordance with some other embodiments of the present disclosure;

FIG. 31 is a diagram showing a test result of chromaticity coordinates, in accordance with yet some other embodiments of the present disclosure;

FIG. 32 is a diagram showing a test result of color shift of white light at viewing angles, in accordance with yet some other embodiments of the present disclosure;

FIG. 33 is a diagram showing a test result of brightness attenuation curves of white light at viewing angles, in accordance with some other embodiments of the present disclosure;

FIG. 34 is a diagram showing spectra of different light-emitting materials, in accordance with some embodiments of the present disclosure;

FIG. 35 is a diagram showing a test result of a relationship between a dopant concentration of a light-emitting material, luminous efficiency and chromaticity coordinate, in accordance with some other embodiments of the present disclosure;

FIG. 36 is a diagram showing a test result of a relationship between a chromaticity coordinate and color gamut coverage, in accordance with yet some other embodiments of the present disclosure;

FIG. 37 is a diagram showing a test result of chromaticity coordinates, in accordance with yet some other embodiments of the present disclosure; and

FIG. 38 is a diagram showing a test result of color shift of white light at viewing angles, in accordance with yet some other embodiments of the present disclosure.

### DESCRIPTION OF THE INVENTION

The technical solutions in some embodiments of the present disclosure will be described clearly and completely with reference to the accompanying drawings. However, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “included, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” and “second” may explicitly or implicitly include one or more of the features. In the description of the embodiments of the present disclosure, the term “a plurality of” or “the plurality of” means two or more unless otherwise specified.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The phrase “applicable to” or “configured to” used herein means an open and inclusive expression, which does not exclude devices that are applicable to or configured to perform additional tasks or steps.

The term such as “about”, “substantially” or “approximately” as used herein includes a stated value and an average value within an acceptable range of deviation of a particular value determined by a person of ordinary skilled in the art, considering measurement in question and errors associated with measurement of a particular quantity (i.e., limitations of a measurement system).

The term such as “parallel”, “perpendicular” or “equal” as used herein includes a stated case and a case similar to the stated case within an acceptable range of deviation determined by a person of ordinary skill in the art, considering measurement in question and errors associated with measurement of a particular quantity (i.e., limitations of a measurement system). For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown in a rectangular shape generally has a feature of being curved. Therefore, the regions shown in the accompanying drawings are schematic in nature, and their shapes are not intended to show actual shapes of the regions in an apparatus, and are not intended to limit the scope of the exemplary embodiments.

Some embodiments of the present disclosure provide a display apparatus. The display apparatus provided in the embodiments of the present disclosure may be any apparatus that displays images whether in motion (e.g., videos) or stationary (e.g., still images) and whether textual or graphical. More specifically, it is expected that the embodiments may be implemented in or associated with a variety of electronic devices. The variety of electronic devices may include (but are not limit to), for example, mobile telephones, wireless devices, personal data assistants (PDAs), hand-held or portable computers, GPS receivers/navigators, cameras, MP4 video players, video cameras, game consoles, watches, clocks, calculators, TV monitors, flat panel displays, computer monitors, car displays (such as odometer displays), navigators, cockpit controllers and/or displays, camera view displays (such as rear view camera displays in vehicles), electronic photos, electronic billboards or signs, projectors, architectural structures, packagings, and aesthetic structures (such as displays for images of a piece of jewelry).

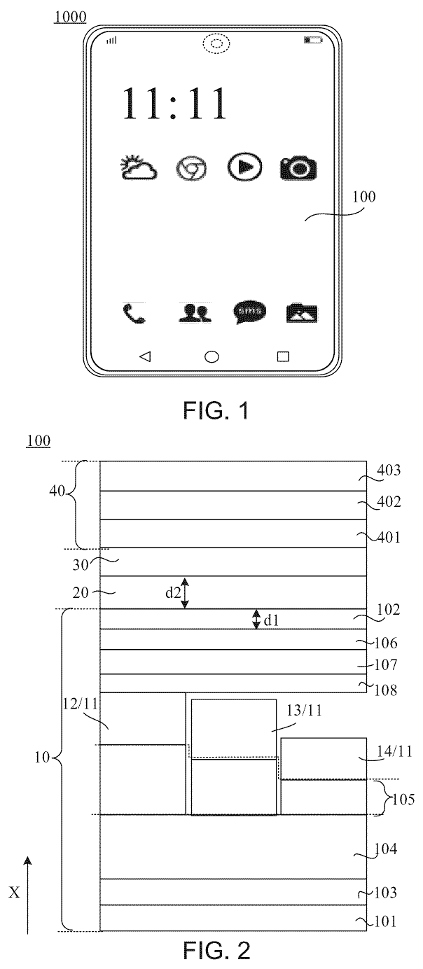

As shown in FIG. 1, the embodiments of the present disclosure will be illustrated by taking an example in which the display apparatus is a mobile phone 1000. The mobile phone 1000 includes a display panel 100. The mobile phone 1000 further includes: a frame, a circuit board, a driver chip and other electronic accessories. The display panel 100 is disposed in the frame, and the driver chip is used to drive the display panel 100 to display images.

In some embodiments, as shown in FIG. 2, the display panel 100 includes light-emitting devices 10. For example, the light-emitting devices 10 include active matrix organic light-emitting devices (AMOLEDs), the AMOLEDs matches the BT2020 color gamut standard (that is, Rx is 0.708, Ry is 0.292, Gx is 0.17, Gy is 0.797, Bx is 0.131 and By is 0.046), and the development of AMOLED high color gamut technology needs to achieve a purpose that the color gamut coverage is greater than or equal to 93% BT2020 color gamut coverage @CIE1931 (≥93% BT2020 color gamut coverage @CIE1931) or greater than or equal to 95% BT2020 color gamut coverage @CIE1976 (≥95% BT2020 color gamut coverage @CIE1976). Here, Rx and Ry are red chromaticity coordinates, Gx and Gy are green chromaticity coordinates, and Bx and By are blue chromaticity coordinates. Conventional AMOLEDs may achieve that By is 0.046, but the difficulty lies in how to achieve deep red whose Rx is greater than or equal to 0.705 (Rx≥0.705) and deep green whose Gx is greater than or equal to 0.17 (Gx≤0.17).

It should be noted that BT2020 refers to the color gamut standard. 93% BT2020 means that the color gamut coverage accounts for 93% of the BT2020 color gamut range. “@CIE1931” and “@CIE1976” refer to different chromaticity coordinate standards. For example, “93% BT2020 color gamut coverage @CIE1931” means that in the 1931 standard system, the color gamut coverage accounts for 93% of the BT2020 color gamut range; and “95% BT2020 color gamut coverage @CIE1976” means that in the 1976 standard system, the color gamut coverage accounts for 95% of the BT2020 color gamut range.

Based on this, as shown in FIG. 2, the embodiments of the present disclosure provide a display panel 100. The display panel 100 includes: a first electrode layer 101 and a second electrode layer 102. The first electrode layer 101 includes a reflective electrode layer. The second electrode layer 102 is arranged opposite to the first electrode layer 101. The second electrode layer 102 includes a transflective electrode layer.

The display panel 100 further includes a light-emitting layer 11, and the light-emitting layer 11 is located between the first electrode layer 101 and the second electrode layer 102.

It should be noted that the first electrode layer 101, light-emitting layer 11 and second electrode layer 102 constitute the light-emitting devices 10. The first electrode layer 101 includes anodes of the light-emitting devices 10, and the second electrode layer 102 includes cathodes of the light-emitting devices 10; or, the first electrode layer 101 includes the cathodes of the light-emitting devices 10, and the second electrode layer 102 includes the anodes of the light-emitting devices 10. The embodiments of the present disclosure will be described by taking an example in which the first electrode layer 101 includes the anodes of the light-emitting devices 10 and the second electrode layer 102 includes the cathodes of the light-emitting devices 10.

For example, the first electrode layer 101 includes the reflective electrode layer, which means that the first electrode layer 101 includes reflective electrode(s). The reflective electrode is used to reflect light incident on the first electrode layer 101. The first electrode layer 101 may be of a single-layer structure or a stacked structure. The reflective electrode refers to an electrode with a reflectivity greater than 90%.

The second electrode layer 102 includes the transflective electrode layer, which means that the second electrode layer 102 includes transflective electrode(s). The transflective electrode is used to reflect part of light incident on the second electrode layer 102 and to transmit part of the light incident on the second electrode layer 102. The transflective electrode refers to an electrode with a reflectivity in a range of 50% to 60%. In this way, the first electrode layer 101 and the second electrode layer 102 form a resonant cavity. The light-emitting layer 11 is located between the first electrode layer 101 and the second electrode layer 102. That is, the light-emitting layer 11 is located in the resonant cavity. The intensity of light of a certain wavelength emitted by the light-emitting layer 11 will be increased, and the spectrum of the light of the certain wavelength is will be narrowed. The resonant cavity may enable a large part of the light emitted by the light-emitting layer 11 to exit the display panel 100 through the second electrode layer 102, thereby improving the luminous efficiency of the light-emitting devices 10.

For example, as shown in FIG. 2, at least one of a hole injection layer 103, a hole transport layer 104 or an electron blocking layer 105 is further provided between the first electrode layer 101 and the light-emitting layer 11. At least one of an electron injection layer 106, an electron transport layer 107 and a hole blocking layer 108 is further provided between the second electrode layer 102 and the light-emitting layer 11.

In the case where the display panel 100 further includes the hole injection layer 103, the hole transport layer 104 and the electron blocking layer 105, the hole injection layer 103, the hole transport layer 104 and the electron blocking layer 105 are sequentially stacked in a direction away from the first electrode layer 101. In the case where the display panel 100 further includes the electron injection layer 106, the electron transport layer 107 and the hole blocking layer 108, the electron injection layer 106, the electron transport layer 107 and the hole blocking layer 108 are sequentially stacked in a direction away from the second electrode layer 102.

The light-emitting layer 11 includes a plurality of light-emitting portions, and materials of the plurality of light-emitting portions include: a host material and a light-emitting material. The plurality of light-emitting portions include a plurality of red light-emitting portions 12, a plurality of blue light-emitting portions 14, and a plurality of green light-emitting portions 13.

It should be noted that the red light-emitting portions 12 are configured to emit red light, the blue light-emitting portions 14 are configured to emit blue light, and the green light-emitting portions 13 are configured to emit green light. The plurality of red light-emitting portions 12, the plurality of blue light-emitting portions 14 and the plurality of green light-emitting portions 13 cooperate with each other to realize the full-color display of the display panel 100. For example, the plurality of red light-emitting portions 12, the plurality of blue light-emitting portions 14 and the plurality of green light-emitting portions 13 cooperate with each other to enable the display panel 100 to display a white picture.

The light-emitting material of at least one red light-emitting portion 12 among the plurality of red light-emitting portions 12 includes a deep red phosphorescent material, and a peak of a photoluminescence spectrum of the deep red phosphorescent material is in a range of 630 nm to 650 nm.

It should be noted that singlet excitons and triplet excitons, generated by the phosphorescent material after being excited, transition to the ground state, leading to light emission; therefore, the internal quantum efficiency (IQE) of the phosphorescent light-emitting device 10 reaches 100%.

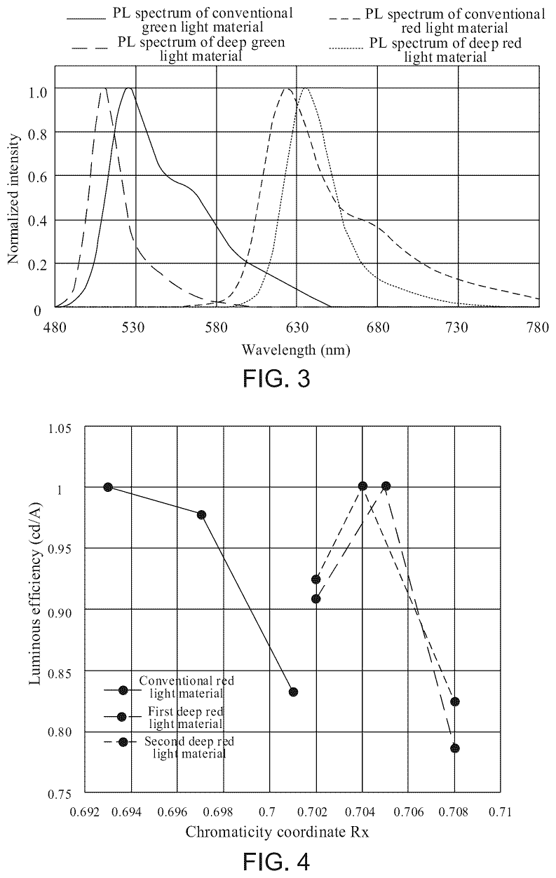

As shown in FIG. 3 and Table 1, the conventional red light material is, for example, a conventional red fluorescent material, and the deep red light material is, for example, a deep red phosphorescent material. Compared with the conventional red light material, the peak of the photoluminescence (PL) spectrum of the deep red light material is red-shifted by 10 nm to 20 nm. The peak of the photoluminescence spectrum of the light-emitting material of the red light-emitting portion 12 is required to be greater than or equal to 630 nm. Therefore, by using the deep red phosphorescent material with the peak of the photoluminescence spectrum in a range of 630 nm to 650 nm, it may be possible to meet the requirements of high color gamut technology development.

It should be noted that after being excited, the fluorescent material will generate singlet excitons and triplet excitons in a ratio of 25:75; fluorescence is emitted when 25% of singlet excitons transition to the ground state; and no light is emitted when 75% of triplet excitons transition to the ground state.

TABLE 1
Photoluminescence spectra of different materials

| | Peak wavelength | Full width at half |
|---|---|---|
| Material type | (nm) | maximum (nm) |
| Conventional | 610 to 620 | 25 to 30 |
| red light | | |
| material | | |
| Deep red light | 630 to 640 | 20 to 25 |
| material | | |

In some examples, as shown in FIG. 4, a chromaticity coordinate range for an optimal luminous efficiency of the light-emitting device 10 of the conventional red light material is Rx<0.695. In order to achieve a high color gamut, when a microcavity length of the light-emitting device 10 is forcibly increased to increase the chromaticity coordinate Rx, the luminous efficiency of the light-emitting device 10 is significantly reduced due to the mismatch between the microcavity gain spectrum and the electroluminescence spectrum of the light-emitting device 10. When the chromaticity coordinate Rx is increased from 0.693 to 0.701, the luminous efficiency is reduced by 17%.

However, a chromaticity coordinate range for an optimal luminous efficiency (luminous efficiency attenuation amount≤10%) of the light-emitting device 10 of the deep red light material is 0.702≤Rx≤0.706, and the high color gamut requirement is satisfied.

It should be noted that a first deep red light material includes: an iridium complex, and a second deep red light material includes: a platinum complex.

In some examples, the chromaticity coordinate Rx of the red light emitted by the deep red phosphorescent material is in a range of 0.703 to 0.705.

For example, the deep red phosphorescent material is selected from any one of an iridium complex, a platinum complex, a zinc complex, a lithium complex and a beryllium complex.

By using the deep red phosphorescent material that the chromaticity coordinate Rx of the emitted red light is in a range of 0.703 to 0.705, the color shift problem of white light at viewing angles may be reduced while the increase of the color gamut of the light-emitting device 10 is guaranteed.

It should be noted that, as shown in FIG. 2, a direction perpendicular to the display panel 100 is a first direction X. When the display panel 100 is viewed at different viewing angles, the color shift problem may occur. Different viewing angles refer to that a viewer views the display panel 100 at a certain angle to the first direction X on a light-exit side of the display panel 100. For example, a viewing angle of 30° refers to viewing the display panel 100 at an angle of 30° to the first direction X.

The following description introduces the relationships between the chromaticity coordinates, and the color gamut, the color shift of white light at viewing angles, and the luminous efficiency when the deep red phosphorescent material with the chromaticity coordinate Rx in a range of 0.703 to 0.705 is used.

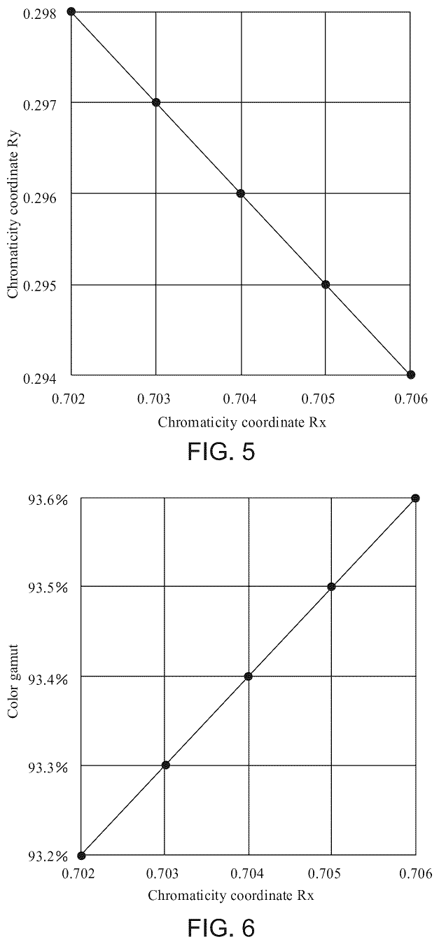

FIG. 5 shows a corresponding relationship between Rx and Ry in the chromaticity coordinate range (Rx>0.7) of the deep red phosphorescent material. It can be seen from the figure that as Rx increases, Ry decreases by the same amount. This variation trend of Rx and Ry is conducive to increasing the color gamut.

Since Rx and Ry change by the same amount, on the premise that the chromaticity coordinates (Gx, Gy) of the green light-emitting portion 13 are fixed at (0.163, 0.761) and the chromaticity coordinates (Bx, By) of the blue light-emitting portion 14 are fixed at (0.140, 0.042), as shown in FIG. 6, when Rx is increased continuously from 0.702 to 0.706, the color gamut is increased continuously.

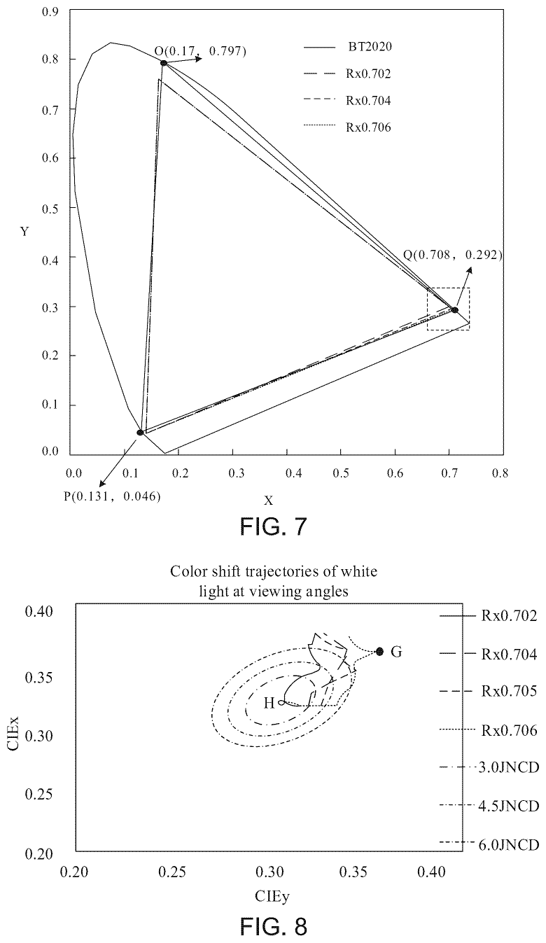

FIG. 7 is a chromaticity coordinate diagram, where the pattern indicated by the BT2020 has three vertices, denoted as O (0.17, 0.797), P (0.131, 0.046), and Q (0.708, 0.292), respectively. A region defined by the three vertices is a region with a largest color gamut.

It should be noted that chromaticity coordinates are coordinates of color, also called a color system. The commonly used chromaticity coordinates now have a horizontal axis as X and a vertical axis as Y, and (X, Y) is used to indicate a color. The BT2020 stipulates that the standard red chromaticity coordinates are Q (0.708, 0.292), the standard green chromaticity coordinates are O (0.17, 0.797), the standard blue chromaticity coordinates are P (0.131, 0.046), and the pure white light chromaticity coordinates are (0.33, 0.33). In the chromaticity coordinate diagram, when the value of the horizontal axis X and the value of the vertical axis Y are both around 0.3, the color shown in the chromaticity coordinate diagram is white. When the value of the horizontal axis X is greater than 0.3 and greater than the value of the vertical axis Y, which is referred to as X greater than Y, most of colors shown in the chromaticity coordinate diagram are red. When the value of the vertical axis Y is greater than 0.3 and greater than the value of the horizontal axis X, which is referred to as X less than Y, most of colors shown in the chromaticity coordinate diagram are green.

As shown in FIG. 7, an overlapping area of the pattern indicated by Rx and the pattern indicated by the BT2020 is indicative of the size of the color gamut under the chromaticity coordinate. The larger the overlapping area, the larger the color gamut. For example, the overlapping area of the pattern indicated by “Rx0.72” and the pattern indicated by the BT2020 is indicative of the color gamut under the chromaticity coordinate; the overlapping area of the pattern indicated by “Rx0.74” and the pattern indicated by BT2020 is indicative of the color gamut under the chromaticity coordinate; and the overlapping area of the pattern indicated by “Rx0.76” and the pattern indicated by the BT2020 is indicative of the color gamut under the chromaticity coordinate. Table 2 shows an optical corresponding relationship between red chromaticity coordinates and white light at viewing angles. In combination with FIG. 7 and Table 2, it can be seen that when Rx is continuously increased from 0.702 to 0.706, Ry is reduced from 0.298 to 0.294. Therefore, as shown in FIG. 7, in the dotted box, when Rx is continuously increased from 0.702 to 0.706, Ry is reduced from 0.298 to 0.294, and the color gamut is continuously increased as the coordinates are closer to the coordinates Q (0.708, 0.292).

TABLE 2
Optical corresponding relationship between red chromaticity
coordinates and white light at viewing angles

| | | | | | Brightness attenuation of | | |
|---|---|---|---|---|---|---|---|
| Chromaticity | | Color shift of white light at | | | white light at viewing | | |
| coordinates | | viewing angles (JNCD) | | | angles | | |
| Rx | Ry | 30° | 45° | 60° | 30° | 45° | 60° |
| 0.702 | 0.298 | 0.6 | 1.0 | 5.0 | 34% | 67% | 81% |
| 0.704 | 0.296 | 2.5 | 2.6 | 5.9 | 33% | 66% | 80% |
| 0.705 | 0.295 | 3.6 | 3.8 | 6.0 | 32% | 65% | 80% |
| 0.706 | 0.294 | 4.9 | 5.5 | 6.7 | 30% | 64% | 80% |

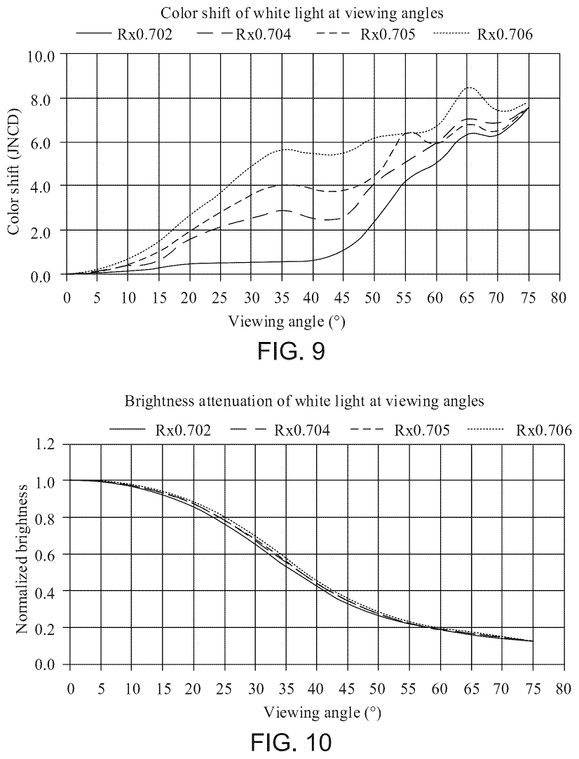

FIG. 8 is a diagram showing color shift trajectories of white light at viewing angles, where the center point H of the ellipses 3.0JNCD (JNCD is a standard for measuring screen color accuracy), 4.5JNCD, and 6.0JNCD is at the coordinates (0.33, 0.33), which are the pure white light chromaticity coordinates. Based on numerical values of chromaticity coordinates X and Y (i.e., CIEx and CIEy) in the figure, a color indicated by a region where the chromaticity coordinates are located may be determined. As for the chromaticity coordinates X and Y and the indicated color, reference may be made to the above description of chromaticity coordinate diagram, details will not be repeated here. It can be understood that, the inflection point G of the curve in the figure is a color shift value at a viewing angle of 30°; and the greater the distance from the center point H to the inflection point G, the greater the color shift. FIG. 9 is a diagram showing curves of color shift of white light at viewing angles. It can be seen from Table 2 and FIGS. 8 and 9 that, as the color gamut increases, reddening of white light at small viewing angles (being less than or equal to 30° (≤)) 30° increases, and the color shift values at viewing angles continues to deteriorate. FIG. 10 shows brightness attenuation curves. The increase of Rx has little effect on the brightness attenuation of white light at viewing angles. Considering that when Rx≥0.703, the BT2020 color gamut coverage is ≥93% @CIE1931 and ≥95% @CIE1976, in order to balance the color gamut and the color shift of white light at viewing angles, the preferred chromaticity coordinate range of deep red light is 0.703≤Rx≤0.705.

From the above description of the red chromaticity coordinates and color shift of white light at viewing angles, it can be seen that the preferred chromaticity coordinate range of deep red light 0.703≤Rx≤0.705, which may balance the color gamut and color shift of white light at viewing angles. In this range, when Rx=0.705, the color gamut is optimal, but reddening of white light at small viewing angles is more serious. In order to increase the color gamut as much as possible and reduce the color shift deterioration of white light at small viewing angles, the following embodiments will be introduced.

As shown in FIG. 2, the display panel 100 further includes a covering layer 20. The covering layer 20 is disposed on a side of the second electrode layer 102 away from the light-emitting layer 11. A thickness d1 of the second electrode layer 102 is in a range of 160 Å to 170 Å, and a thickness d2 of the covering layer 20 is in a range of 950 Å to 1000 Å.

For example, the thickness d1 of the second electrode layer 102 is 160 Å, 165 Å, or 170 Å, which is not limited here. The thickness d2 of the covering layer 20 is 950 Å, 960 Å, 970 Å, 980 Å, 990 Å or 1000 Å, which is not limited here.

In the related art, the thickness d1 of the second electrode layer 102 of the display panel 100 is less than 160 Å, and the thickness d2 of the covering layer 20 is generally in a range of 700 Å to 800 Å. However, in the embodiments of the present disclosure, the thickness d1 of the second electrode layer 102 is in a range of 160 Å to 170 Å, and the thickness d2 of the covering layer 20 is in a range of 950 Å to 1000 Å. That is to say, in the embodiments of the present disclosure, the thickness d1 of the second electrode layer 102 and the thickness d2 of the covering layer 20 are increased, so that the brightness of red at small viewing angles (≤30°) may be individually adjusted. As a result, the aggravation of reddening of white light at small viewing angles (≤30°) is ameliorated.

In order to prove that increasing the thickness d1 of the second electrode layer 102 and the thickness d2 of the covering layer 20 may ameliorate the aggravation of reddening of white light at small viewing angles (≤30°), the following data are provided.

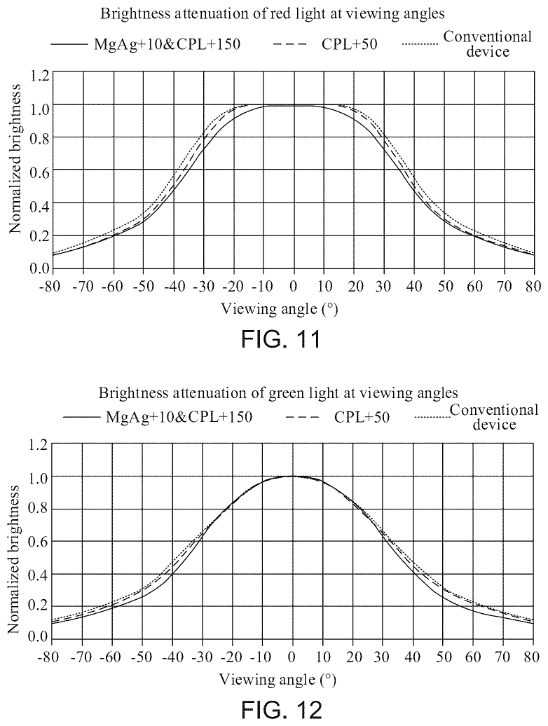

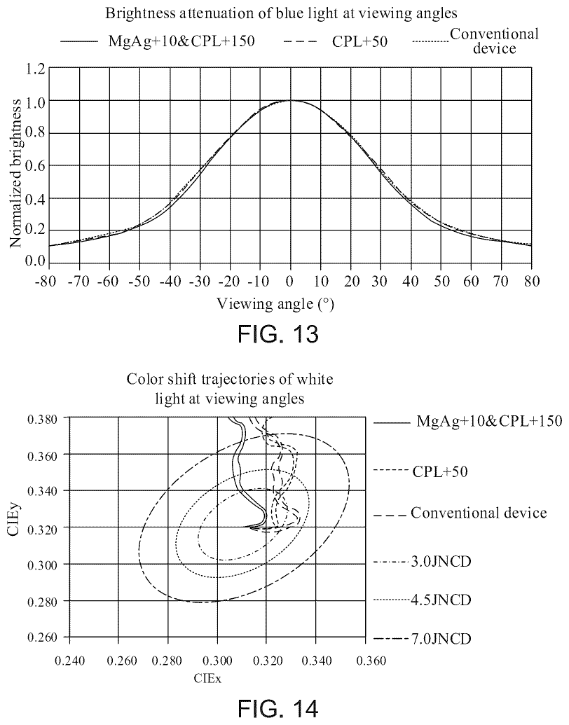

As shown in FIGS. 11 to 13, the “conventional device” means that the thickness d1 of the second electrode layer 102 and the thickness d2 of the covering layer 20 are conventional and are not increased. This embodiment will be described by taking an example in which the thickness d1 of the second electrode layer 102 in the conventional device is 150 Å, and the thickness d2 of the covering layer 20 in the conventional device is 800 Å.

Based on the thickness d1 of the second electrode layer 102 and the thickness d2 of the covering layer 20 of the conventional device, “MgAg+10&CPL+150” means that the thickness d1 of the second electrode layer 102 is increased by 10 Å, and the thickness d2 of the covering layer 20 is increased by 150 Å. That is, the thickness d2 of the covering layer 20 is 950 Å, and the thickness d1 of the second electrode layer 102 is 160 Å.

“CPL+50” means that the thickness d2 of the covering layer 20 is increased by 50 Å. That is, the thickness d2 of the covering layer 20 is 850 Å.

It can be seen that, when the thickness d2 of the covering layer 20 is 850 Å (increased by 50 Å), the brightness attenuation of red light at full viewing angles is slightly accelerated, the brightness attenuation of green light at large viewing angles (≥) 45° is slightly accelerated, and the brightness attenuation of blue light at viewing angles is not affected. When the thickness d2 of the covering layer 20 is 950 Å (increased by 150 Å) and the thickness d1 of the second electrode layer 102 is 160 Å (increased by 10 Å), the brightness attenuation of red light at full viewing angles is significantly accelerated, the brightness attenuation of green light at medium and large viewing angles (≥30°) is accelerated, and the brightness attenuation of blue light at viewing angles is not affected. Compared with the case in which the covering layer 20 is thickened by 50 Å, in the technical solution provided by the embodiments where the thickness d2 of the covering layer 20 is increased by 150 Å and the thickness d1 of the second electrode layer 102 is increased by 10 Å, only the brightness attenuation of red light within a range of small viewing angles (≤30°) is significantly accelerated, and the problem of reddening of white light at small viewing angles (≤30°) is significantly ameliorated.

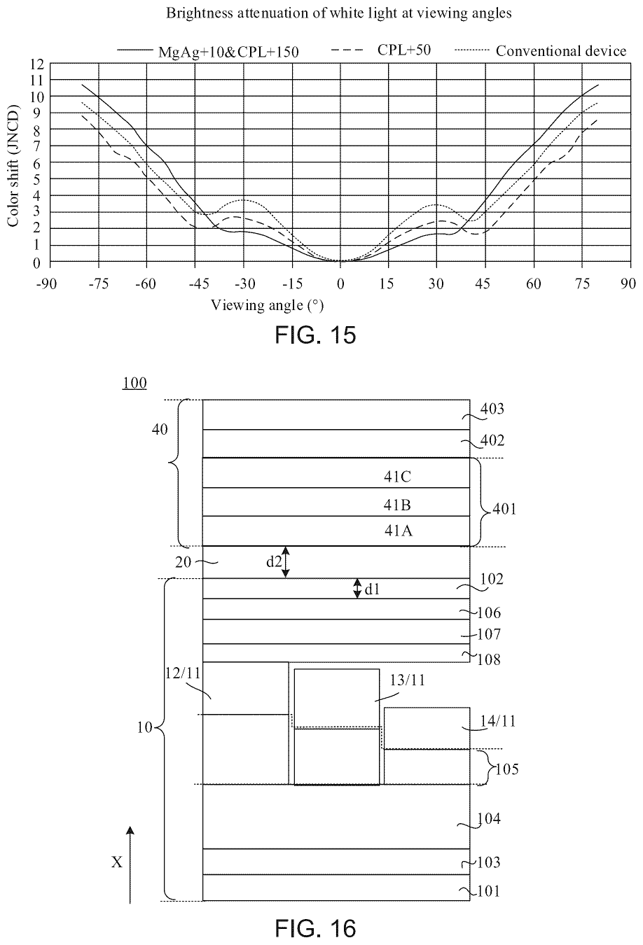

FIG. 14 is a diagram showing color shift trajectories of white light at viewing angles. FIG. 15 is a diagram showing brightness attenuation of white light at viewing angles. FIGS. 14 and 15 further illustrate that in the example where the covering layer 20 is thickened by 150 Å and the second electrode layer 102 is thickened by 10 Å, the problem of reddening of white light at small viewing angles (≤30°) is significantly ameliorated.

In some embodiments, as shown in FIG. 2, the display panel 100 further includes an optical control layer 30 and an encapsulation layer 40. A material of the optical control layer 30 includes lithium fluoride. The encapsulation layer 40 includes a first encapsulation layer 401, a second encapsulation layer 402, and a third encapsulation layer 403 that are sequentially stacked in a direction away from the light-emitting devices 10. For example, the first encapsulation layer 401 may be of a single-layer structure.

For example, a material of the first encapsulation layer 401 includes silicon oxynitride, a material of the second encapsulation layer 402 includes an inkjet-printed organic material, and a material of the third encapsulation layer 403 includes silicon nitride.

In order to further eliminate the problem of reddening of white light at small viewing angles (≤30°), the following embodiments will be introduced.

In some embodiments, as shown in FIG. 16, the encapsulation layer 40 of the display panel 100 includes a first encapsulation layer 401, and the first encapsulation layer 401 is disposed on a side of the covering layer 20 away from the second electrode layer 102. The first encapsulation layer 401 is of a multi-layer structure, and includes a first encapsulation sub-layer 41A, a second encapsulation sub-layer 41B and a third encapsulation sub-layer 41C that are sequentially arranged in a direction away from the covering layer 20. A refractive index n1 of the covering layer 20 is greater than a refractive index n2 of the first encapsulation sub-layer 41A, the refractive index n2 of the first encapsulation sub-layer 41A is less than a refractive index n3 of the second encapsulation sub-layer 41B, and the refractive index n3 of the second encapsulation sub-layer 41B is greater than a refractive index n4 of the third encapsulation sub-layer 41C. That is, n1>n2, n2<n3, and n3>n4. A structure is formed, whose refractive index is high/low/high/low from the covering layer 20 to the third encapsulation sub-layer 41C.

For example, materials of the first encapsulation sub-layer 41A, the second encapsulation sub-layer 41B, and the third encapsulation sub-layer 41C each include silicon oxynitride.

In the embodiments of forming the structure whose refractive index is high/low/high/low from the covering layer 20 to the third encapsulation sub-layer 41C, it may be possible to eliminate the technical problem of reddening of white light of the light-emitting device 10 at small viewing angles (≤30°). As shown in FIG. 16, there is no optical control layer 30 provided in the display panel 100, and a refractive index of the optical control layer 30 cannot satisfy the fabrication of the above-mentioned structure with high/low/high/low refractive index. Therefore, in order to eliminate the technical problem of reddening of white light of the light-emitting device 10 at small viewing angles (≤30°), the first encapsulation layer 401 is set to be of a multi-layer structure whose refractive index meets the requirements.

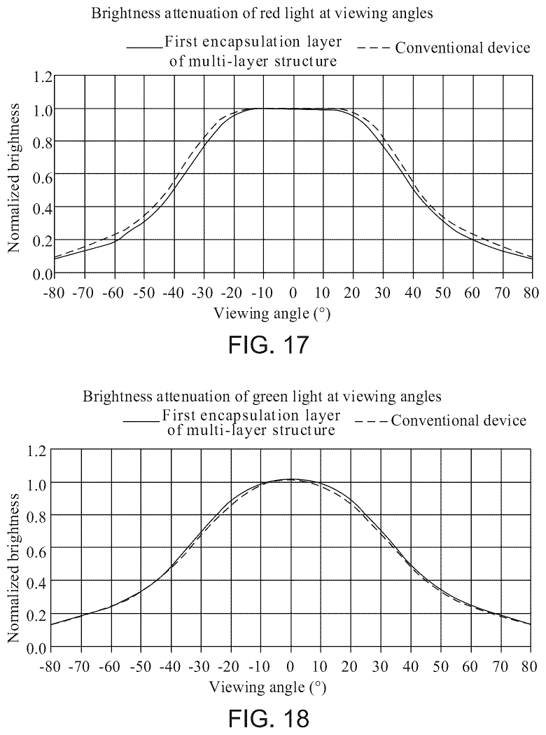

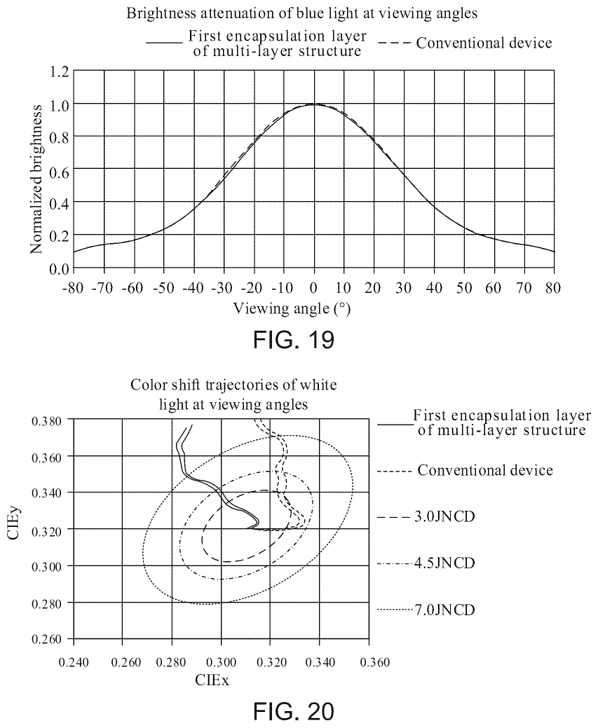

As shown in FIGS. 17 to 19, the first encapsulation layer in the display panel 100 shown in FIG. 16 is of a multi-layer structure, and the first encapsulation layer in the conventional device is of a single-layer structure. It can be seen from FIG. 17 that, compared with the conventional technology, in the display panel 100 where the first encapsulation layer is of a multi-layer structure, brightness attenuation of red light at full viewing angles is significantly accelerated; it can be seen from FIG. 18 that, although brightness attenuation of green light at small viewing angles (≤30°) is also accelerated, the degree of acceleration of green light is significantly less than the degree of acceleration of red light; it can be seen from FIG. 19 that, brightness attenuation of blue light at viewing angles is not affected. Since the first encapsulation layer is of a multi-layer structure, a structure is formed, whose refractive index is high/low/high/low from the covering layer 20 to the third encapsulation sub-layer 41C. Therefore, the brightness attenuation of red light is accelerated within a range of small viewing angles (≤30°), and the problem of reddening of white light at small viewing angles (≤30°) is effectively eliminated.

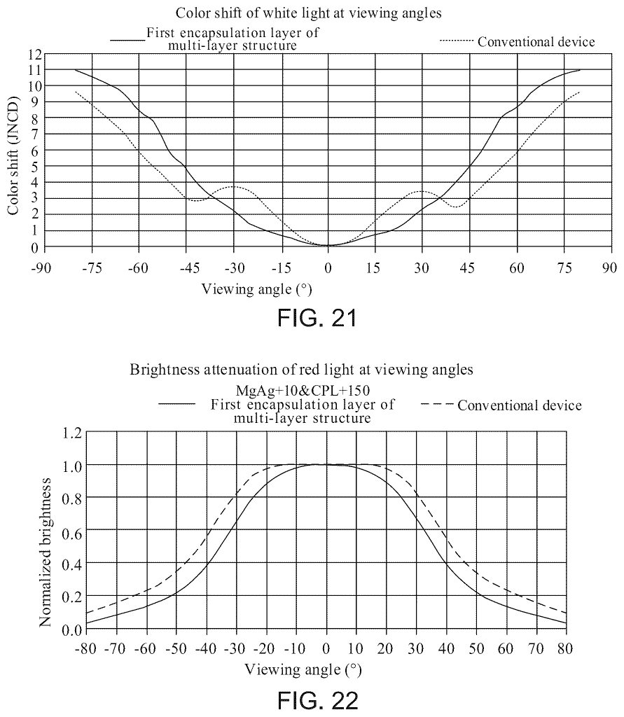

FIG. 20 is a diagram showing color shift trajectories of white light at viewing angles. FIG. 21 is a diagram showing curves of color shift of white light at viewing angles. It can be seen from FIG. 20 that, compared with the conventional device, the device with the first encapsulation layer of a multi-layer structure has a color shift trajectory that is far away from a red region (a region close to the chromaticity coordinate Q (0.708, 0.292)); and it can also be seen that, the reddening of white light at small viewing angles (≤30°) is eliminated. It can be seen from FIG. 21 that, the color shift values of white light at small viewing angles (≤30°) are significantly reduced.

In some embodiments, the refractive index n1 of the covering layer 20 is in a range of 1.7 to 1.8; the refractive index n2 of the first encapsulation sub-layer 41A is in a range of 1.4 to 1.52; the refractive index n3 of the second encapsulation sub-layer 41B is in a range of 1.7 to 1.8; and the refractive index n4 of the third encapsulation sub-layer 41C is in a range of 1.55 to 1.65.

For example, the refractive index n1 of the covering layer 20 is 1.7, 1.75 or 1.8; the refractive index n2 of the first encapsulation sub-layer 41A is 1.4, 1.43, 1.47, 1.5 or 1.52; the refractive index n3 of the second encapsulation sub-layer 41B is 1.7, 1.75 or 1.8; and the refractive index n4 of the third encapsulation sub-layer 41C is 1.55, 1.6 or 1.65.

In some embodiments, referring to the structure of the display panel 100 in FIG. 16, the thickness d1 of the second electrode layer 102 of the display panel 100 is in a range of 160 Å to 170 Å; the thickness d2 of the covering layer 20 is in a range of 950 Å to 1000 Å; and the first encapsulation layer 401 includes: a first encapsulation sub-layer 41A, a second encapsulation sub-layer 41B and a third encapsulation sub-layer 41C that are sequentially arranged in the direction away from the covering layer 20. Therefore, it may be possible to achieve amelioration of color shift of white light at full viewing angles.

As shown in FIGS. 22 to 24, the “conventional device” means that the thickness d1 of the second electrode layer 102 and the thickness d2 of the covering layer 20 are conventional and are not increased. That is, the thickness d1 of the second electrode layer 102 is 150 Å, and the thickness d2 of the covering layer 20 is 800 Å. The first encapsulation layer 401 is of a single-layer structure.

“MgAg+10&CPL+150” and the first encapsulation layer 401 of a multi-layer structure mean that: the thickness d1 of the second electrode layer 102 is increased by 10 Å, and the thickness d2 of the covering layer 20 is increased by 150 Å (that is, the thickness d2 of the covering layer 20 is 950 Å, and the thickness d1 of the second electrode layer 102 is 160 Å); the first encapsulation layer 401 includes: a first encapsulation sub-layer 41A, a second encapsulation sub-layer 41B and a third encapsulation sub-layer 41C, and a structure is formed, whose refractive index is high/low/high/low from the covering layer 20 to the third encapsulation sub-layer 41C.

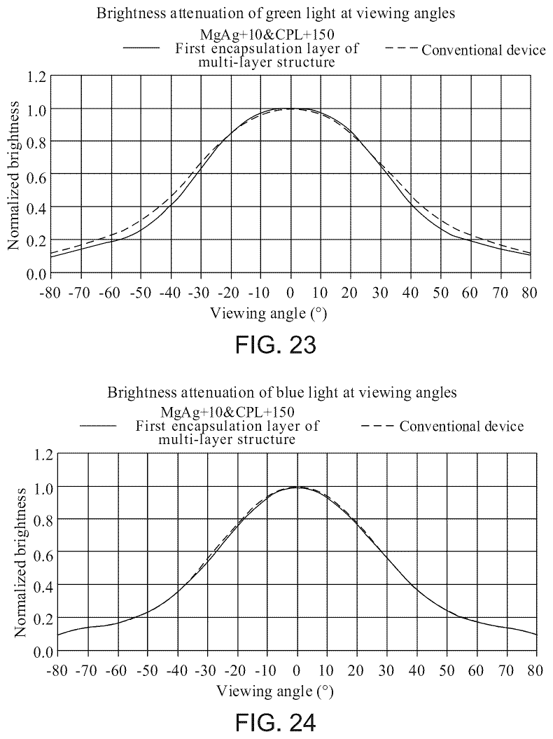

As can be seen from the figures, as shown in FIG. 22, the brightness attenuation of red light at full viewing angles is greatly accelerated; as shown in FIG. 23, the brightness attenuation of green light at medium and large viewing angles (≥30°) is accelerated; as shown in FIG. 24, the brightness attenuation of blue light at viewing angles is not affected. As a result, only the brightness attenuation of red light is greatly accelerated within a range of small viewing angles (≤30°).

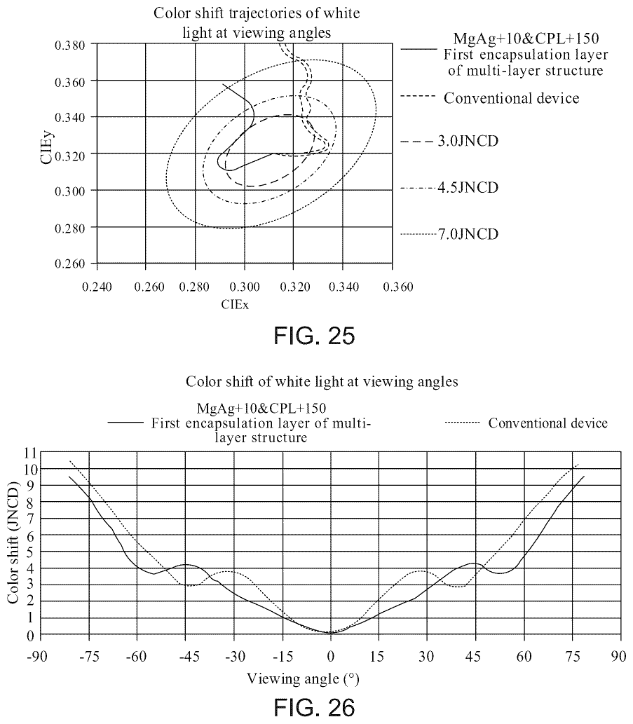

FIG. 25 is a diagram showing color shift trajectories of white light at viewing angles. FIG. 26 is a diagram showing color shift of white light at viewing angles. From the above description of the chromaticity coordinate diagram, it can be seen that the standard green chromaticity coordinates are O (0.17, 0.797), the standard blue chromaticity coordinates are P (0.131, 0.046), and the pure white light chromaticity coordinates are (0.33, 0.33). In the chromaticity coordinate diagram, when the value of the horizontal axis X and the value of the vertical axis Y are both around 0.3, the color shown in the chromaticity coordinate diagram is white. When the value of the horizontal axis X is greater than 0.3 and greater than the value of the vertical axis Y, which is referred to as X greater than Y, most of colors shown in the chromaticity coordinate diagram are red. When the value of the vertical axis Y is greater than 0.3 and greater than the value of the horizontal axis X, which is referred to as X less than Y, most of colors shown in the chromaticity coordinate diagram are green.

As shown in FIGS. 25 and 26, the color shift trajectory of white light at small viewing angles changes from red to cyan, and it starts to turn green at a medium viewing angle (=45°), thus eliminating the technical problem of reddening of white light of the light-emitting devices 10 at small viewing angles (≤30°).

In some embodiments, as shown in FIGS. 2 and 16, a material of at least one green light-emitting portion 13 among the plurality of green light-emitting portions 13 further includes a green thermally activated delayed fluorescence material, and the light-emitting material of the green light-emitting portion 13 includes a deep green fluorescent material, and the peak of the photoluminescence spectrum of the deep green fluorescent material is in a range of 500 nm to 520 nm.

TABLE 3
Photoluminescence spectra of different materials

| | Peak wavelength | Full width at half |
|---|---|---|
| Material type | (nm) | maximum (nm) |
| Conventional | 525 to 535 | 25 to 30 |
| green material | | |
| Deep green | 505 to 515 | 15 to 20 |
| light material | | |

As shown in FIG. 3 and Table 3, the conventional green material includes a conventional green fluorescent material, and the deep green light material includes a deep green fluorescent material. Compared with conventional green light material, the peak of the PL spectrum of the deep green light material is blue-shifted by 10 nm to 20 nm. The peak of the photoluminescence spectrum of the light-emitting material of the green light-emitting portion 13 is required to be less than or equal to 515 nm. Therefore, by using the deep green fluorescent material that the peak of the photoluminescence spectrum peak is in a range of 500 nm to 520 nm, it may be possible to meet the requirements of high color gamut technology development.

Moreover, as shown in FIG. 3, Table 3 and Table 4, the full width at half maximum of the deep green light material is significantly narrowed by 5 to 10 nm, and the full width at half maximum of the deep green light material is required to be less than or equal to 20 nm. Even when the full width at half maximum is less than or equal to 20 nm, as the full width at half maximum narrows and Gy is increased at the same Gx, the color gamut is increased accordingly.

TABLE 4
Relationship between full width at half maximum and chromaticity
coordinates of deep green light materials

| | Full width at half | | |
|---|---|---|---|
| Material type | maximum (nm) | Gx | Gy |
| First deep | 17 | 0.165 | 0.761 |
| green light | | | |
| material | | | |
| Second deep | 19 | 0.165 | 0.754 |
| green light | | | |
| material | | | |

The first deep green light material includes carbazole derivatives, and the second deep green light material includes diaminoanthracene derivatives.

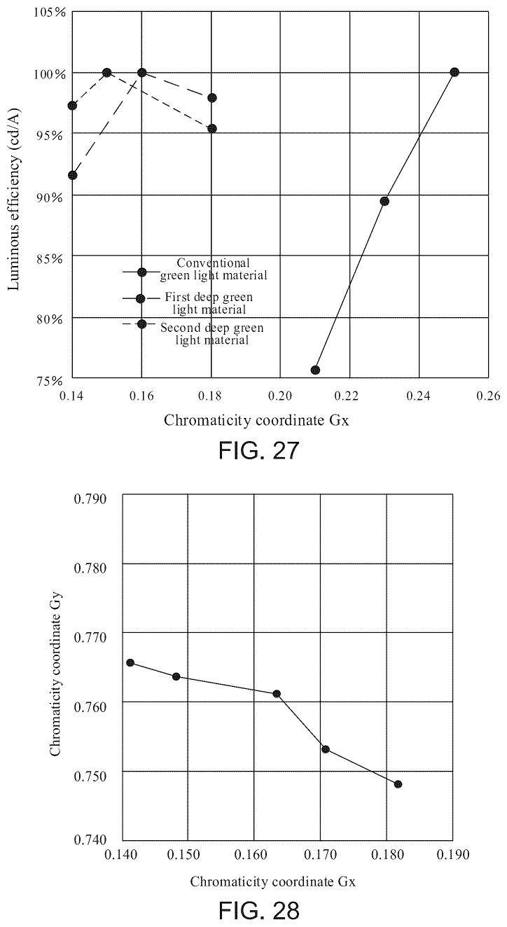

In some examples, as shown in FIG. 27, a chromaticity coordinate range for an optimal luminous efficiency of the light-emitting device 10 of the conventional green light material is Gx>0.24. In order to achieve deep green, when the microcavity length is significantly reduced to reduce Gx, the microcavity gain spectrum and the electroluminescence spectrum are mismatched, causing a significant decrease in luminous efficiency. When Gx is reduced from 0.25 to 0.21, the efficiency is reduced by 24%.

However, a chromaticity coordinate range for an optimal luminous efficiency (efficiency attenuation range≤10%) of the light-emitting device 10 of the deep green light material is 0.14≤Gx≤0.18, and the high color gamut requirement is satisfied.

Therefore, by using the deep green fluorescent material that the peak of the photoluminescence spectrum peak is in a range of 500 nm to 520 nm, the luminous efficiency of the light-emitting device 10 is guaranteed, and the requirements of high color gamut green spectrum of the light-emitting device 10 may be achieved.

In some examples, the chromaticity coordinate Gx of green light emitted by the deep green fluorescent material is in a range of 0.155 to 0.165.

For example, the deep green fluorescent material is selected from any one of coumarins, carbazole derivatives, diaminoanthracene derivatives, and pyrazoloquinoxaline derivatives.

By using the deep green fluorescent material with the chromaticity coordinate Gx in a range of 0.155 to 0.165, the green light-emitting portion 13 of the light-emitting device 10 may achieve the purpose of high color gamut and small color shift value of white light at viewing angles.

FIG. 28 shows a corresponding relationship between Gx and Gy in a chromaticity coordinate range (Gx<0.2) of the deep green light material. It can be seen from the figure that as Gx decreases, Gy increases; and this variation trend of Gx and Gy is conducive to increasing the color gamut.

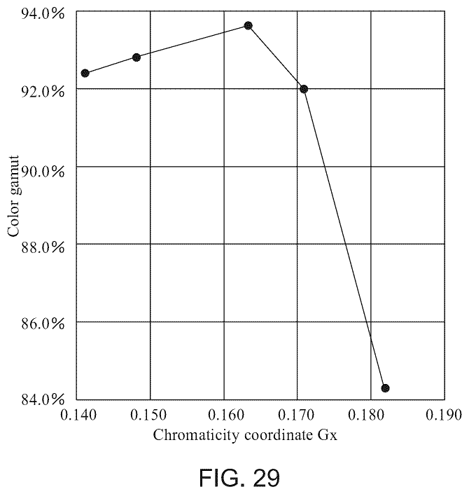

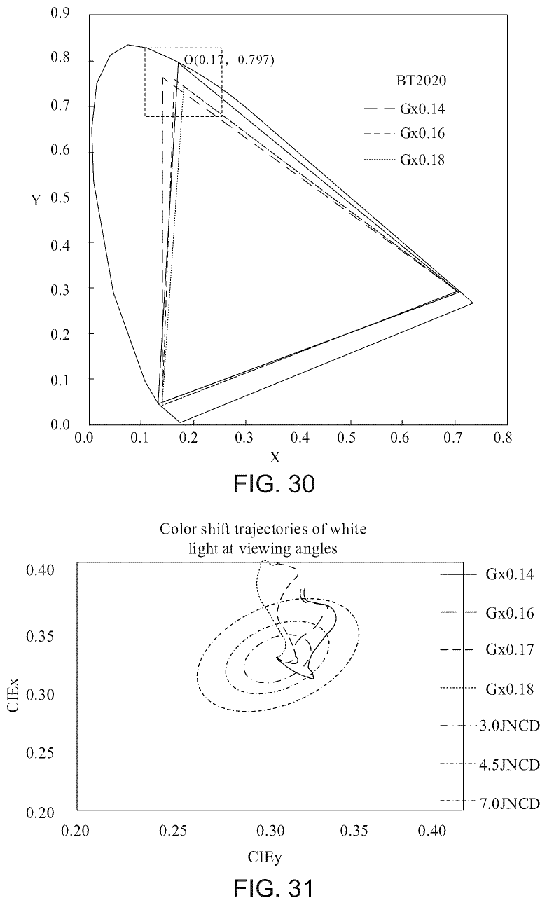

However, since the increasing amount of Gy is significantly less than the decreasing amount of Gx (due to the full width at half maximum), on the premise that the chromaticity coordinates (Rx, Ry) of the red light-emitting portion 12 are fixed at (0.705, 0.295) and the chromaticity coordinates (Bx, By) of the blue light-emitting portion 14 are fixed at (0.140, 0.042), as shown in FIG. 29, when Gx decreases from 0.18 to 0.14, the color gamut first increases and then decreases. That is, the decrease in Gx cannot continue to contribute to the color gamut, and the color gamut is the largest when Gx is approximately equal to 0.16. As shown in FIG. 30, in the dotted box, when Gx takes different values, the closer a vertex of a pattern indicated by Gx in the region is to O (0.17, 0.797), the larger the color gamut is. It can be seen that when Gx is approximately equal to 0.16, the color gamut is the largest.

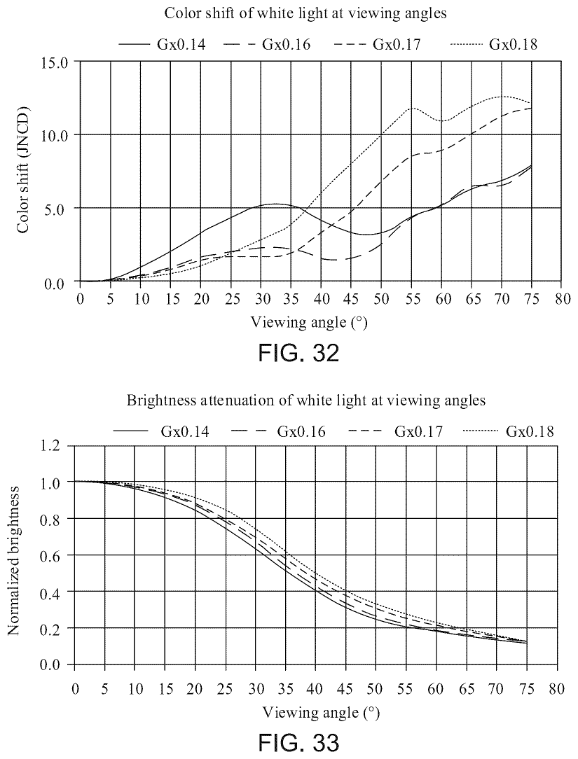

FIG. 31 is a diagram showing color shift trajectories of white light at viewing angles. FIG. 32 is a diagram showing curves of color shift of white light at viewing angles. As shown in Table 5 and FIGS. 31 and 32, when Gx decreases from 0.18 to 0.16, the trajectory becomes shorter and shorter, which indicates the mitigation of white light turning green at large viewing angles (≥30°) and the reduction of color shift value; when Gx decreases from 0.16 to 0.14, the reddening of white light at small viewing angles (≤30°) is aggravated and the color shift value is increased; and when Gx=0.16, the color shift of white light at viewing angles is minimal.

TABLE 5
Optical correspondence between green chromaticity
coordinates and white light at viewing angles

| | | | | | Brightness attenuation of | | |
|---|---|---|---|---|---|---|---|
| Chromaticity | | Color shift of white light at | | | white light at viewing | | |
| coordinates | | viewing angles (JNCD) | | | angles | | |
| Gx | Gy | 30° | 45° | 60° | 30° | 45° | 60° |
| 0.14 | 0.77 | 5.2 | 3.4 | 5.1 | 37% | 68% | 81% |
| 0.16 | 0.76 | 2.3 | 1.5 | 5.3 | 33% | 66% | 81% |
| 0.17 | 0.75 | 1.7 | 4.8 | 8.9 | 30% | 62% | 78% |
| 0.18 | 0.75 | 2.8 | 8.0 | 10.9 | 26% | 59% | 77% |

FIG. 33 is a diagram showing brightness attenuation of white light at viewing angles. It can be seen that, the reduction of Gx significantly accelerates the brightness attenuation of white light at viewing angles. Therefore, considering the color gamut, and color shift and brightness attenuation of white light at viewing angles, the range of the chromaticity coordinate of the deep green light material is 0.155≤Gx≤0.165.

In some embodiments, referring to the structure of the display panel 100 in FIG. 2, and the light-emitting layer 11 for the light-emitting devices 10 includes: red light-emitting portions 12, green light-emitting portions 13 and blue light-emitting portions 14. A material of at least one of the plurality of green light-emitting portions 13 further includes a green thermally activated delayed fluorescence material. The light-emitting material of the green light-emitting portion 13 includes a deep green fluorescent material. A peak of a photoluminescence spectrum of the deep green fluorescent material is in a range of 500 nm to 520 nm. There is no limitation on the materials of the red light-emitting portions 12 and the blue light-emitting portions 14 of the light-emitting devices 10.

As for the introduction to the performance of the green light-emitting portion 13 including the deep green fluorescent material, reference may be made to the above description, and details will not be repeated here.

In some embodiments, referring to the structure of the display panel 100 in FIG. 2, the light-emitting layer 11 for the light-emitting devices 10 includes: red light-emitting portions 12, green light-emitting portions 13 and blue light-emitting portions 14. A material of the red light-emitting portion 12 includes: a host material and a light-emitting material.

In order to improve the luminous efficiency, the material of the red light-emitting portion 12 further includes a red thermally activated delayed fluorescence (TADF) sensitizer, which is denoted as RTADF. Through the reverse intersystem crossing mechanism of the RTADF sensitizer, the energy of triplet excitons is effectively used and is transferred to the fluorescent material, thereby improving the luminous efficiency.

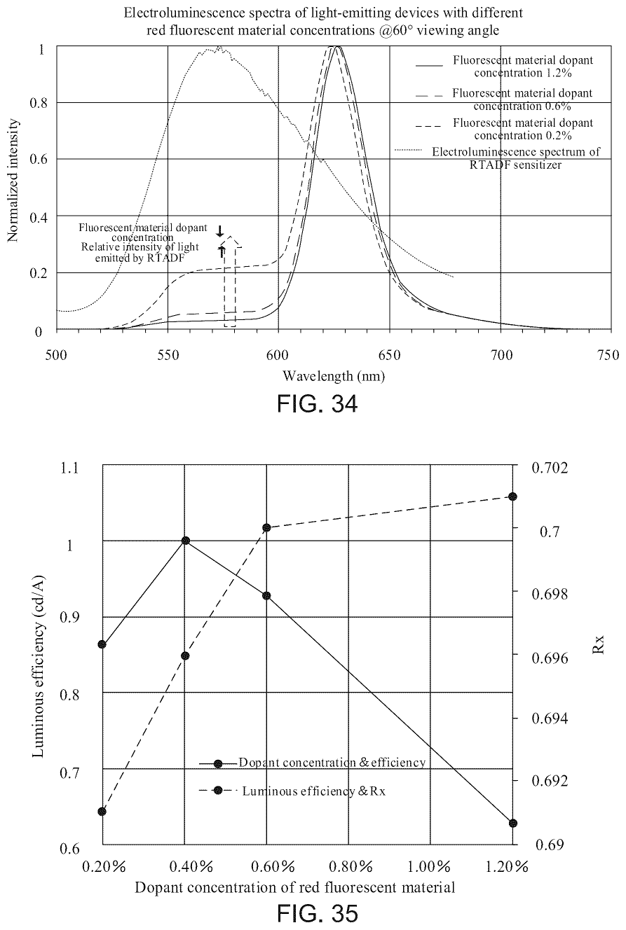

However, a dopant concentration of the fluorescent material in the red light-emitting portion 12 cannot give consideration to both the light emitting of the RTADF sensitizer and the luminous efficiency. As shown in FIG. 34, in a case where an angle between the sight line of the viewer and the first direction X (as shown in FIG. 2) is 60° (represented as @60° viewing angle in FIG. 34), when the dopant concentration of the fluorescent material is low, the energy transfer from the RTADF sensitizer to the fluorescent material is incomplete, resulting in significant light emitting of the RTADF sensitizer. Since the RTADF sensitizer emits orange-red light, as shown in FIG. 35, the light emitting of the RTADF sensitizer will cause the chromaticity coordinate Rx to be reduced significantly, resulting in the inability to achieve deep red. However, when the dopant concentration of the fluorescent material is increased and the light emitting of the RTADF sensitizer is ameliorated, a significant decrease in luminous efficiency will be caused.

Therefore, when the dopant concentration of the red fluorescent material is not appropriate, the existing light-emitting device 10 with the RTADF sensitizer and fluorescent material cannot meet the requirements of high color gamut and high luminous efficiency. Reducing the dopant concentration of the red fluorescent material will cause the orange-yellow light emitted by the RTADF and hinder the achievement of deep red. Increasing the dopant concentration of the red fluorescent material will reduce the molecular distance between RTADF and the fluorescent material, causing some triplet excitons formed by RTADF to be transferred to the fluorescent material and annihilated before being converted into singlet excitons, significantly reducing the luminous efficiency.

In light of this, as shown in FIG. 2, a display panel 100 is provided, and the display panel 100 includes: a first electrode layer 101 and a second electrode layer 102. The first electrode layer 101 includes a reflective electrode layer, the second electrode layer 102 is arranged opposite to the first electrode layer 101, and the second electrode layer 102 includes a transflective electrode layer.

As for the introduction to the first electrode layer 101 and the second electrode layer 102, reference may be made to the above description, and details will not be repeated here.

The display panel 100 further includes a light-emitting layer 11, and the light-emitting layer 11 is located between the first electrode layer 101 and the second electrode layer 102. The light-emitting layer 11 includes a plurality of light-emitting portions, and materials of the plurality of light-emitting portions include: a host material and a light-emitting material. The plurality of light-emitting portions include a plurality of red light-emitting portions 12, a plurality of blue light-emitting portions 14, and a plurality of green light-emitting portions 13.

The light-emitting material of the red light-emitting portion 12 further include a red thermally activated delayed fluorescence material and a deep red fluorescent material. A peak of a photoluminescence spectrum of the deep red fluorescent material is in a range of 630 nm to 650 nm. In the red light-emitting portion 12, a ratio of mass of the deep red fluorescent material to a sum of mass of the host material, the red thermally activated delayed fluorescence material and the deep red fluorescent material is in a range of 0.4% to 0.6%.

In some examples, as shown in FIG. 3 and Table 1, the deep red light material is the deep red fluorescent material. Compared with the conventional red light material, the peak of the photoluminescence (PL) spectrum of the deep red fluorescent material is red-shifted by 10 nm to 20 nm. The peak of the photoluminescence spectrum of the light-emitting material of the red light-emitting portion 12 is required to be greater than or equal to 630 nm. Therefore, by using the deep red fluorescent material with the peak of the photoluminescence spectrum in a range of 630 nm to 650 nm, it may be possible to meet the requirements of high color gamut technology development.

For example, the ratio of mass of the deep red fluorescent material to a sum of mass of the host material, the red thermally activated delayed fluorescence material and the deep red fluorescent material is 0.4%, 0.45%, 0.5% or 0.6%, which is not limited here.

Since the ratio of mass of the deep red fluorescent material to a sum of mass of the host material, the red thermally activated delayed fluorescence material and the deep red fluorescent material is in a range of 0.4% to 0.6%, the requirements of higher luminous efficiency may be satisfied while the requirements of high color gamut may be satisfied to a certain extent.

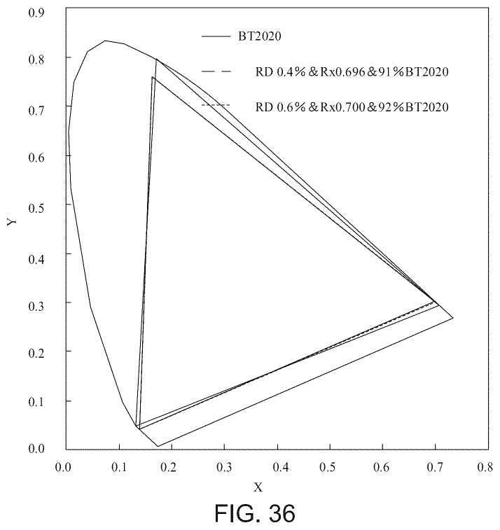

As shown in FIGS. 35 and 36, when the dopant concentration (RD %) of the red fluorescent material is 0.4%, the corresponding chromaticity coordinate Rx is equal to 0.696 (Rx=0.696), and the color gamut coverage is 91% BT2020. When the dopant concentration of the red fluorescent material is 0.6%, the corresponding chromaticity coordinate Rx=0.700, and the color gamut coverage is 92% BT2020.

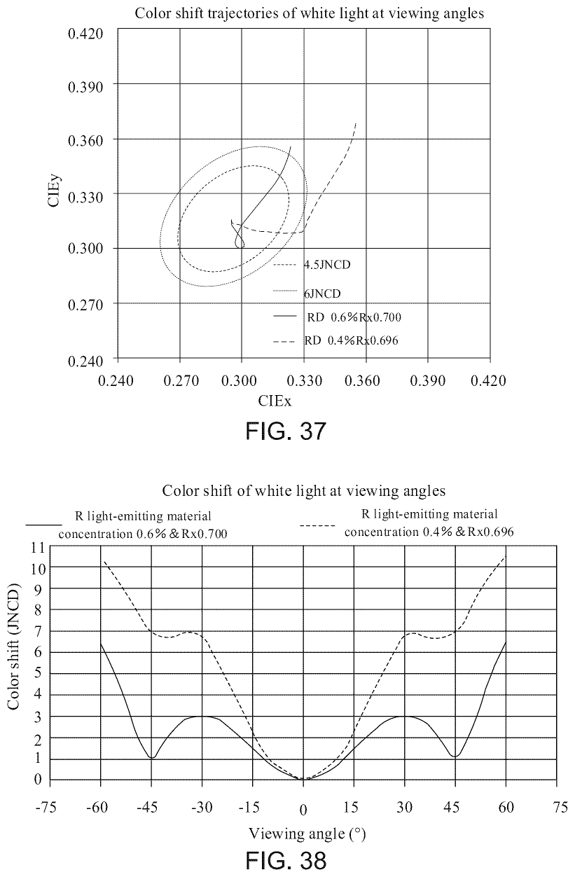

FIG. 37 is a diagram showing color shift trajectories of white light at viewing angles. FIG. 38 is a diagram showing color shift of white light at viewing angles. It can be seen from the figures that, when the dopant concentration of the red fluorescent material is 0.4%, the reddening of white light at small viewing angles (≤30°) is more serious and the color shift value is larger. When the dopant concentration of the red fluorescent material is 0.6%, the reddening of white light at small viewing angles (≤30°) is mitigated to a certain extent, the color shift is ameliorated, the color gamut is improved, and the luminous efficiency is reduced by 5%. Therefore, in this embodiment, by setting the ratio of mass of the deep red fluorescent material to a sum of mass of the host material, the red thermally activated delayed fluorescence material and the deep red fluorescent material in a range of 0.4% to 0.6%, it may be possible to give attention to both the color gamut and luminous efficiency to a certain extent, and to select the optimal dopant concentration of the deep red fluorescent material.

In some examples, the chromaticity coordinate Rx of the red light emitted by the deep red fluorescent material is in a range of 0.703 to 0.705. By using the deep red fluorescent material that the chromaticity coordinate Rx of the emitted red light is in a range of 0.703 to 0.705, the color shift problem of white light at viewing angles may be reduced while the increase of the color gamut of the light-emitting device 10 is guaranteed.

For example, the deep red fluorescent material includes any one of dicyanomethylene-4H-pyran (DCM)-based dopants, DCM derivative dopants, auxiliary dopants, conjugated condensed rings, porphyrin macrocycles, and aromatic acid.

In some embodiments, referring to the structure of the display panel 100 shown in FIG. 2 or 16, the light-emitting material of the red light-emitting portion 12 of the light-emitting device 10 includes the red thermally activated delayed fluorescence material and the deep red fluorescent material; in the red light-emitting portion 12, the ratio of mass of the deep red fluorescent material to a sum of mass of the host material, the red thermally activated delayed fluorescence material and the deep red fluorescent material is in a range of 0.4% to 0.6%; at least one green light-emitting portion 13 of the plurality of green light-emitting portions 13 for light-emitting device(s) 10 further includes a green thermally activated delayed fluorescence material; the light-emitting material of the green light-emitting portion 13 includes the deep green fluorescent material, the peak of the photoluminescence spectrum of the deep green fluorescent material is in a range of 500 nm to 520 nm, and the chromaticity coordinate Gx of the green light emitted by the deep green fluorescent material is in a range of 0.155 to 0.165; and the light-emitting material of at least one of the plurality of blue light-emitting portions 14 for light-emitting device(s) 10 is a blue fluorescent light-emitting material. Therefore, the design of the display panel 100 with full fluorescence and high color gamut is realized.

The foregoing descriptions are merely specific implementation manners of the present disclosure, but the protection scope of the present disclosure is not limited thereto, any changes or replacements that a person skilled in the art could conceive of within the technical scope of the present disclosure shall be included in the protection scope of the present disclosure. Therefore, the protection scope of the present disclosure shall be subject to the protection scope of the claims.

1. A display panel, comprising:
a first electrode layer including a reflective electrode layer;
a second electrode layer arranged opposite to the first electrode layer, and the second electrode layer including a transflective electrode layer; and
a light-emitting layer located between the first electrode layer and the second electrode layer, wherein the light-emitting layer includes a plurality of light-emitting portions, and a material of each of the plurality of light-emitting portions includes: a host material and a light-emitting material; the plurality of light-emitting portions include a plurality of red light-emitting portions, a plurality of blue light-emitting portions and a plurality of green light-emitting portions;
wherein a light-emitting material of at least one red light-emitting portion of the plurality of red light-emitting portions includes a deep red phosphorescent material, and a peak of a photoluminescence spectrum of the deep red phosphorescent material is in a range of 630 nm to 650 nm.

2. The display panel according to claim 1, wherein a chromaticity coordinate Rx of red light emitted by the deep red phosphorescent material is in a range of 0.703 to 0.705.

3. The display panel according to claim 1, wherein the deep red phosphorescent material is selected from any one of: an iridium complex, a platinum complex, a zinc complex, a lithium complex, and a beryllium complex.

4. The display panel according to claim 1, wherein a material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

5. The display panel according to claim 4, wherein a chromaticity coordinate Gx of green light emitted by the deep green fluorescent material is in a range of 0.155 to 0.165.

6. The display panel according to claim 4, wherein the deep green fluorescent material is selected from any one of: coumarins, carbazole derivatives, diaminoanthracene derivatives, and pyrazoloquinoxaline derivatives.

7. The display panel according to claim 1, further comprising: a covering layer disposed on a side of the second electrode layer away from the light-emitting layer, wherein
a thickness of the second electrode layer is in a range of 160 Å to 170 Å;
a thickness of the covering layer is in a range of 950 Å to 1000 Å.

8. The display panel according to claim 7, further comprising: a first encapsulation layer disposed on a side of the covering layer away from the second electrode layer;
wherein the first encapsulation layer is of a multi-layer structure, and includes a first encapsulation sub-layer, a second encapsulation sub-layer and a third encapsulation sub-layer that are sequentially arranged in a direction away from the covering layer;
a refractive index of the covering layer is greater than a refractive index of the first encapsulation sub-layer;
the refractive index of the first encapsulation sub-layer is less than a refractive index of the second encapsulation sub-layer; and
the refractive index of the second encapsulation sub-layer is greater than a refractive index of the third encapsulation sub-layer.

9. The display panel according to claim 8, wherein
the refractive index of the covering layer is in a range of 1.7 to 1.8;
the refractive index of the first encapsulation sub-layer is in a range of 1.4 to 1.52;
the refractive index of the second encapsulation sub-layer is in a range of 1.7 to 1.8; and
the refractive index of the third encapsulation sub-layer is in a range of 1.55 to 1.65.

10. The display panel according to claim 7, further comprising:
an optical control layer disposed on a side of the covering layer away from the second electrode layer; and
a first encapsulation layer being of a single-layer structure and being disposed on a side of the optical control layer away from the covering layer.

11. The display panel according to claim 8, further comprising: a second encapsulation layer and a third encapsulation layer sequentially disposed on a side of the first encapsulation layer away from the covering layer.

12. The display panel according to claim 11, wherein a material of the first encapsulation layer includes silicon oxynitride;
a material of the second encapsulation layer includes an organic material; and
a material of the third encapsulation layer includes silicon nitride.

13. A display panel, comprising:
a first electrode layer including a reflective electrode layer;
a second electrode layer arranged opposite to the first electrode layer, and the second electrode layer including a transflective electrode layer; and
a light-emitting layer located between the first electrode layer and the second electrode layer, wherein the light-emitting layer includes a plurality of light-emitting portions, and a material of each of the plurality of light-emitting portions includes: a host material and a light-emitting material; the plurality of light-emitting portions include a plurality of red light-emitting portions, a plurality of blue light-emitting portions and a plurality of green light-emitting portions;
wherein a light-emitting material of a red light-emitting portion of the plurality of red light-emitting portions further includes a red thermally activated delayed fluorescence material and a deep red fluorescent material, and a peak of a photoluminescence spectrum of the deep red fluorescent material is in a range of 630 nm to 650 nm; in the red light-emitting portion, a ratio of mass of the deep red fluorescent material to a sum of mass of a host material, the red thermally activated delayed fluorescence material and the deep red fluorescent material is in a range of 0.4% to 0.6%.

14. The display panel according to claim 13, wherein a chromaticity coordinate Rx of red light emitted by the deep red fluorescent material is in a range of 0.703 to 0.705.

15. The display panel according to claim 13, wherein the deep red fluorescent material includes any one of: dicyanomethylene-4H-pyran (DCM)-based dopants, DCM derivative dopants, auxiliary dopants, conjugated condensed rings, porphyrin macrocycles, and aromatic acid.

16. The display panel according to claim 13, wherein a material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

17. The display panel according to claim 16, wherein a chromaticity coordinate Gx of green light emitted by the deep green fluorescent material is in a range of 0.155 to 0.165; and/or
the deep green fluorescent material is selected from any of: coumarins, carbazole derivatives, diaminoanthracene derivatives, and pyrazoloquinoxaline derivatives.

18. (canceled)

19. A display panel, comprising:
a first electrode layer including a reflective electrode layer;
a second electrode layer arranged opposite to the first electrode layer, and the second electrode layer including a transflective electrode layer;
a light-emitting layer located between the first electrode layer and the second electrode layer, wherein the light-emitting layer includes a plurality of light-emitting portions, and a material of each of the plurality of light-emitting portions includes: a host material and a light-emitting material; the plurality of light-emitting portions include a plurality of red light-emitting portions, a plurality of blue light-emitting portions and a plurality of green light-emitting portions;
wherein a material of at least one green light-emitting portion of the plurality of green light-emitting portions further includes a green thermally activated delayed fluorescence material, a light-emitting material of the green light-emitting portion includes a deep green fluorescent material, and a peak of a photoluminescence spectrum of the deep green fluorescent material is in a range of 500 nm to 520 nm.

20. The display panel according to claim 19, wherein a chromaticity coordinate Gx of green light emitted by the deep green fluorescent material is in a range of 0.155 to 0.165; and/or
the deep green fluorescent material is selected from any one of: coumarins, carbazole derivatives, diaminoanthracene derivatives, and pyrazoloquinoxaline derivaties.

21. (canceled)

22. A display apparatus, comprising:
the display panel according to claim 1; and
a driver chip for driving the display panel to display images.
